(19) United States
(12) Patent Application Publication
(10) Pub. No.: US 2005/0260818 A1
(43) Pub. Date: Nov. 24, 2005

(54) Semiconductor device and method for fabricating the same

(75) Inventor: Hideaki Fujiwara, Hashima-Shi (JP)

Correspondence Address: MCDERMOTT WILL & EMERY LLP, 600 13TH STREET, N.W., WASHINGTON, DC, 20005-3096, US

(73) Assignee: SANYO ELECTRIC CO., LTD.

(21) Appl. No.: 11/132,197

(22) Filed: May 19, 2005

(30) Foreign Application Priority Data
May 20, 2004 (JP) 2004-150270

(51) Int. Cl. H01L 21/336

(52) U.S. Cl. 438/300

(57) ABSTRACT

A method for fabricating a semiconductor device includes:isolating a SOI layer on a buried oxide film with a pair of element isolation regions having a perpendicular sidewall; depositing a poly-crystal silicon layer on the isolated SOI layer; implanting a dopant into the poly-crystal silicon layer; depositing a silicon oxide film on the poly-crystal silicon layer; forming a recessed portion by selectively removing the silicon oxide film and the poly-crystal silicon layer in a gate bearing region and then selectively removing the SOI layer in the gate bearing region to a predetermined depth; forming a sidewall spacer on the side wall of the recessed portion; forming source and drain regions by allowing a dopant to diffuse from the poly-crystal silicon layer into the SOI layer; and forming a gate electrode by depositing a gate metal layer after a gate insulating film is formed on the bottom of the recessed portion.

### BACKGROUND OF THE INVENTION

1. Field of the Invention

The present invention relates to a semiconductor devices and a method for fabricating a semiconductor device. More particularly, the invention relates to a field effect transistor which has an elevated source drain structure and a method for fabricating the transistor.

2. Description of the Related Art

These days, with increasing packing densities of semiconductor integrated circuits, MOS-type field effect transistors (MOSFETs) formed on a silicon substrate follow finer design rules in accordance with the scaling law. This causes the concentration of dopants to be increased in a channel-bearing region as well as an inversion layer resulting from an application of a voltage to the gate electrode of the MOSFET to be reduced in thickness. This in turn makes electrons flowing through the channel more readily affected by interface scattering. Additionally, the capacity of the source-drain junction is also increased, which impedes the operation of the MOSFET at higher speeds.

As an approach to these problems, conventionally known is a so-called SOI (Silicon on Insulator) MOSFET which is configured to have a thin semiconductor formed on an insulating film (e.g., see Intel Technology Journal, Vol. 6, Issue 2, which will be referred to as “non-patent document 1” hereinafter).

However, it was conventionally difficult to improve a key function of the MOSFET or mobility due to the increase in interface scattering. The increase in source-drain junction capacity also impedes operations at higher speeds. One of the means for addressing these problems is a SOIFET with an elevated source drain structure; however, conventional techniques such as DSTs(Depleted Substrate Transistors) have been used to provide a sufficient scale of integration through simple processes but with difficulty.

For example, the SOI MOSFET described in the non-patent document 1 is designed to provide an elevated structure to the source and drain, thereby reducing parasitic resistance. However, to realize the elevated source drain structure, the epitaxial process is required, thus making the fabrication process complicated. The structure also causes the sidewall of the source and drain to be inclined, thus resulting in a disadvantage in seeking for a finer design rule and higher scale of integration for a semiconductor device.

### SUMMARY OF THE INVENTION

The present invention was developed in view of the aforementioned problems. It is therefore an object of the present invention to provide a method for fabricating a semiconductor device which realizes a finer design rule and higher scale of integration for the semiconductor device with a simple process. It is another object of the invention to provide a semiconductor device which is fabricated according to the method.

A semiconductor device according to one aspect of the present invention comprises: a substrate having a semiconductor layer formed on an insulating film; perpendicularly elevated source and drain regions at a portion sandwiched between a pair of element isolation regions formed on the substrate; first and second insulating films formed on respective inner sidewalls of the source and drain regions; and a gate electrode, isolated with a gate insulating film, between the first and second insulating films.

In the aforementioned aspect, the device may also comprise: a source sidewall insulating film disposed between the source region and the gate electrode; a drain sidewall insulating film disposed between the drain region and the gate electrode; a source extension region formed under the source sidewall insulating film to connect to the source region; and a drain extension region formed under the drain sidewall insulating film to connect to the drain region. Furthermore, the gate insulating film may contain hafnium, zirconium, or aluminum. The semiconductor device has an elevated source drain structure which employs a so-called high-k film, thereby providing reduced source-drain resistance and enhanced resistance to short-channel effects.

A method for fabricating a semiconductor device according to one aspect of the present invention comprises: isolating a single-crystal silicon layer on an insulating film with a pair of element isolation regions having a perpendicular sidewall; depositing a poly-crystal silicon layer on the isolated single-crystal silicon layer; implanting a dopant into the poly-crystal silicon layer; depositing an insulating film on the poly-crystal silicon layer; forming a recessed portion by selectively removing the insulating film and the poly-crystal silicon layer in a gate bearing region and then selectively removing the single-crystal silicon layer in the gate bearing region to a predetermined depth; forming a sidewall on the sidewall of the recessed portion; forming source and drain regions by allowing a dopant to diffuse from the poly-crystal silicon layer to the single-crystal silicon layer; and forming a gate electrode by depositing a conductive film after a gate insulating film is formed on a bottom of the recessed portion.

According to the method, it is possible to form an elevated source drain structure having perpendicular sidewalls through a simple process without employing the epitaxial process, thereby readily realizing a higher scale of integration and finer design rule in the semiconductor device.

A method for fabricating a semiconductor device according to another aspect of the present invention comprises: isolating a single-crystal silicon layer on an insulating film with a pair of element isolation regions having a perpendicular sidewall; forming a pair of mixed-crystal semiconductors on the isolated single-crystal silicon layer; forming a sidewall on each of sidewalls of the pair of mixed-crystal semiconductors; implanting a dopant into the pair of mixed-crystal semiconductors; and forming a gate insulating film and then depositing a conductive film to thereby form a gate electrode on a bottom of a gate bearing region between the pair of mixed-crystal semiconductors.

According to the method, it is possible to form an elevated source drain structure having perpendicular sidewalls through a simple process without employing the epitaxial process, thereby readily realizing a higher scale of integration and finer design rule in the semiconductor device.

A method for fabricating a semiconductor device according to still another aspect of the present invention comprises: forming an insulating layer on a single-crystal silicon layer on an insulating film; forming a recessed portion having a perpendicular sidewall by selectively removing the insulating layer and the single-crystal silicon layer in a gate bearing region; forming a poly-crystal silicon film on a bottom of the recessed portion and then epitaxially growing the poly-crystal silicon film to form a single-crystal silicon film; forming a pair of gate forming spacers on the single-crystal silicon film, the spacers having a perpendicular sidewall buried in an insulating substance; implanting a dopant into the single-crystal silicon film between the pair of gate forming spacers and into the single-crystal silicon layer outside the pair of gate forming spacers; forming a salicide on top of a region having the dopant implanted therein; removing the pair of gate forming spacers and the underlying insulating substance to form a pair of recessed portions and exposing the single-crystal silicon film on the bottom of the pair of recessed portions; forming a gate insulating film on the bottom of the pair of recessed portions; and then depositing a conductive film to form a pair of gate electrodes via the gate insulating film.

According to the method, it is possible to form an elevated source drain structure having a perpendicular sidewall through a simple process without employing the epitaxial process, thereby readily realizing a higher scale of integration and finer design rule in the semiconductor device.

A method for fabricating a semiconductor device according to still another aspect of the present invention comprises: forming an insulating layer on a single-crystal silicon layer on an insulating film; forming a recessed portion having a perpendicular sidewall by selectively removing the insulating layer and the single-crystal silicon layer in a gate bearing region; forming a poly-crystal silicon film on a bottom of the recessed portion and then epitaxially growing the poly-crystal silicon film to form a single-crystal silicon film; forming a pair of gate forming spacers on the single-crystal silicon film, the spacers having a perpendicular sidewall buried in an insulating substance; selectively removing the single-crystal silicon film between the pair of gate forming spacers and then selectively removing the underlying insulating film to a predetermined depth; forming a poly-crystal silicon film on an inner sidewall of the pair of gate forming spacers; implanting a dopant into the poly-crystal silicon film and into the single-crystal silicon layer outside the pair of gate forming spacers; forming a salicide on top of a region having the dopant implanted therein; removing the pair of gate forming spacers and the underlying insulating substance to form a pair of recessed portions and exposing the single-crystal silicon film on the bottom of the pair of recessed portions; forming a gate insulating film on the bottom of the pair of recessed portions; and then depositing a conductive film to form a pair of gate electrodes via the gate insulating film.

According to the method, it is possible to form an elevated source drain structure having a perpendicular sidewall through a simple process without employing the epitaxial process, thereby readily realizing a higher scale of integration and finer design rule in the semiconductor device.

Incidentally, any combinations of the foregoing components may be encompassed by the scope of the present invention to be protected as a granted patent.

### BRIEF DESCRIPTION OF THE DRAWINGS

FIGS. 1A to 1D are cross-sectional views showing steps of fabricating a semiconductor device according to a first embodiment;

FIGS. 2A to 2D are cross-sectional views showing steps of fabricating the semiconductor device according to the first embodiment;

FIGS. 3A and 3B are cross-sectional views showing steps of fabricating the semiconductor device according to the first embodiment;

FIGS. 4A to 4D are cross-sectional views showing steps of fabricating a semiconductor device according to a second embodiment;

FIGS. 5A to 5C are cross-sectional views showing steps of fabricating the semiconductor device according to the second embodiment;

FIG. 6 is a cross-sectional view showing a step of fabricating the semiconductor device according to the second embodiment;

FIGS. 7A and 7B are cross-sectional views showing steps of fabricating a semiconductor device according to a third embodiment;

FIGS. 8A and 8B are cross-sectional views showing steps of fabricating the semiconductor device according to the third embodiment;

FIG. 9 is a cross-sectional view showing a step of fabricating a semiconductor device according to a fourth embodiment;

FIGS. 10A and 10B are cross-sectional views showing steps of fabricating a semiconductor device according to a fifth embodiment;

FIGS. 11A to 11C are cross-sectional views showing steps of fabricating a semiconductor device according to a sixth embodiment;

FIGS. 12A to 12C are cross-sectional views showing steps of fabricating the semiconductor device according to the sixth embodiment;

FIGS. 13A and 13B are cross-sectional views showing steps of fabricating the semiconductor device according to the sixth embodiment;

FIGS. 14A to 14C are cross-sectional views showing steps of fabricating a semiconductor device according to an eighth embodiment;

FIGS. 15A and 15B are cross-sectional views showing steps of fabricating the semiconductor device according to the eighth embodiment;

FIGS. 16A to 16C are cross-sectional views showing steps of fabricating a semiconductor device according to a ninth embodiment;

FIGS. 17A and 17B are cross-sectional views showing steps of fabricating the semiconductor device according to the ninth embodiment;

FIGS. 18A to 18C are cross-sectional views showing steps of fabricating a semiconductor device according to a tenth embodiment;

FIGS. 19A and 19B are cross-sectional views showing steps of fabricating the semiconductor device according to the tenth embodiment;

FIGS. 20A to 20D are cross-sectional views showing steps of fabricating a semiconductor device according to an eleventh embodiment; and

FIG. 21 is a cross-sectional view showing a step of fabricating the semiconductor device according to the eleventh embodiment.

### DETAILED DESCRIPTION OF THE INVENTION

[First Embodiment]

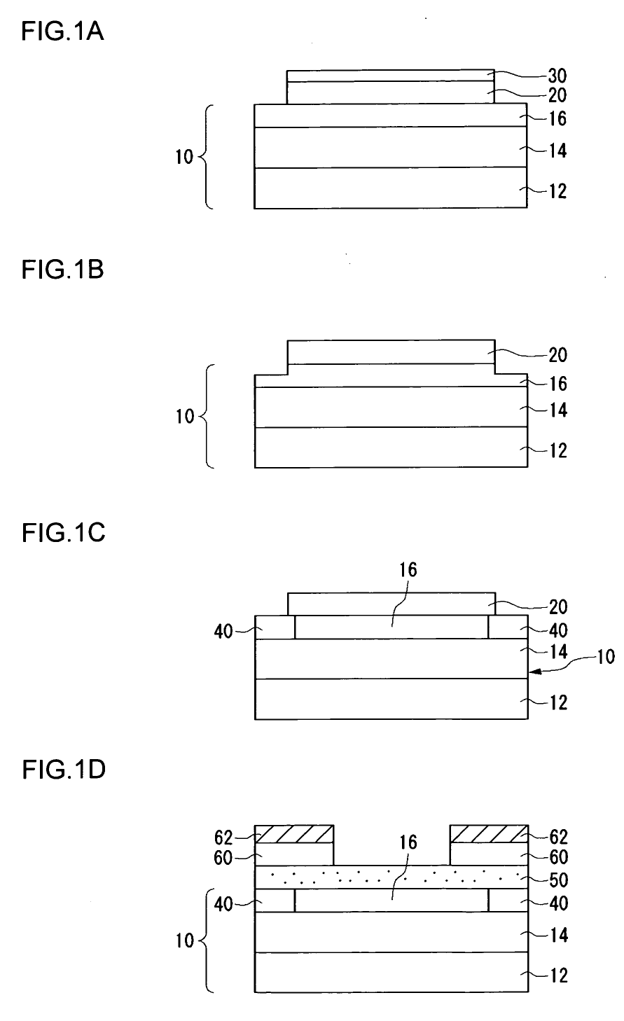

As shown in FIG. 1A, a semiconductor substrate 10 or a SOI substrate includes a Si layer 12, a SOI layer 16 (having a thickness of 100 nm), and a buried oxide film (BOX film) 14 formed between the Si layer 12 and the SOI layer 16. On the semiconductor substrate 10, deposited are a silicon nitride (Si₃N₄) layer 20 and a poly-crystal silicon layer 30.

Subsequently formed on the poly-crystal silicon layer 30 is a patterned resist (not shown) having openings on the ends in the cross-sectional direction of FIG. 1A , and then the end portions of the silicon nitride layer 20 and the poly-crystal silicon layer 30 are selectively removed.

Then, as shown in FIG. 1B, by plasma etching, the poly-crystal silicon layer 30 and the SOI layer 16 are dry etched to be gradually removed. In the step of removing the poly-crystal silicon layer 30 and the SOI layer 16, plasma emissions from the silicon nitride layer 20 are successively detected using an optical sensor (not shown) to set an end point with respect to a point in time at which an emission has reached a predetermined intensity and then terminate the dry etching.

Then, as shown in FIG. 1C, by thermal oxidation such as wet oxidation, element isolation regions 40 are formed in a thickness of 100 nm on both sides of the SOI layer 16.

Then, as shown in FIG. 1D, the silicon nitride layer 20 is removed using hot phosphoric acid, and then a poly-crystal silicon layer 50 is deposited. An ionic dopant such as arsenic ions is implanted into the poly-crystal silicon layer 50 at a dose of about 3E15 cm⁻². Furthermore, by CVD (Chemical Vapor Deposition), a silicon oxide film 60 and a poly-crystal silicon layer 62 are deposited. Thereafter, by employing as an opening of a mask a gate pattern provided through a lithography process, the silicon oxide film 60 and the poly-crystal silicon layer 62 are selectively removed by RIE (Reactive Ion Etching) using the difference in selection ratio between them and the underlying layer. Through this step, there is formed a recessed portion having perpendicular sidewalls with the poly-crystal silicon layer 50 disposed at the bottom thereof.

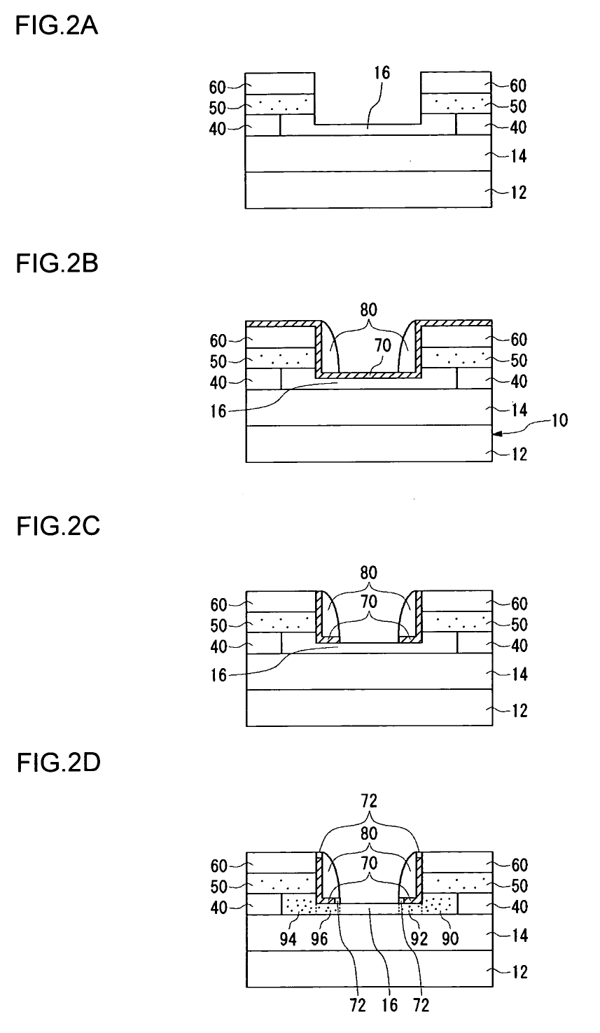

Then, as shown in FIG. 2A, the poly-crystal silicon layer 62 and the poly-crystal silicon layer 50 at the bottom of the recessed portion are gradually etched away. Then, after the poly-crystal silicon layer 50 at the bottom of the recessed portion has been removed, the underlying SOI layer 16 is gradually removed and then the etching is terminated when it is detected based on a change in emission intensity that the silicon oxide film 60 has been exposed. Through this step, the SOI layer 16 in the gate region has been removed to a certain depth, such that the SOI layer 16 in the gate region is reduced in thickness, e.g., to about 20 to 30 nm. At this point in time, there is formed in the gate region a recessed portion having perpendicular sidewalls with the SOI layer 16 at its bottom. In this step, the thickness of the SOI layer 16 in the gate region can be easily changed by controlling the end point of the etching depending on the thickness of the poly-crystal silicon layer 62. The thickness of the SOI layer 16 in the gate region is desirably less than or equal to about one third of the gate length. This allows for preventing a short-channel effect such as the source-drain punch-through.

Then, as shown in FIG. 2B, a poly-crystal silicon layer 70 having a thickness of 20 to 30 nm is deposited on the entire surface. Thereafter, a silicon oxide film of a thickness of 100 nm is deposited on the entire surface, and then by anisotropic etching such as RIE, side wall spacers 80 are formed on the sidewalls of the recessed portion in the gate region.

Then, as shown in FIG. 2C, the poly-crystal silicon layer 70 exposed by RIE is etched away by the thickness of the layer deposited in FIG. 2B.

Then, as shown in FIG. 2D, the exposed surface portion of the SOI layer 16 is thermally oxidized from the surface to a depth of about 20 nm, and thereafter, subjected to heat treatment for 10 to 20 seconds at a temperature of 1000° C. At this time, since the oxidization rate of poly-crystal silicon is greater than that of single-crystal silicon, both the exposed ends of the poly-crystal silicon layer 70 are oxidized deeper (than 20 nm). Thereafter, using DHF (Dilute Hydrofluoric Acid) or BHF (Buffered Hydrofluoric Acid), the silicon oxide film on the surface is washed away by about 20 nm. Through this step, the single-crystal silicon is exposed in the channel portion. On the other hand, both the exposed portion of the poly-crystal silicon layer 70 are covered with a thin silicon oxide film (SiO₂) 72. Furthermore, the dopant diffuses from the poly-crystal. silicon layer 50 into the SOI layer 16 to form a source region 90 and a drain region 94 having a perpendicular sidewall in the SOI layer 16. On both sides of the channel region immediately under the gate, there are also formed a source extension region 92 and a drain extension region 96 which contact with the source region 90 and the drain region 94, respectively.

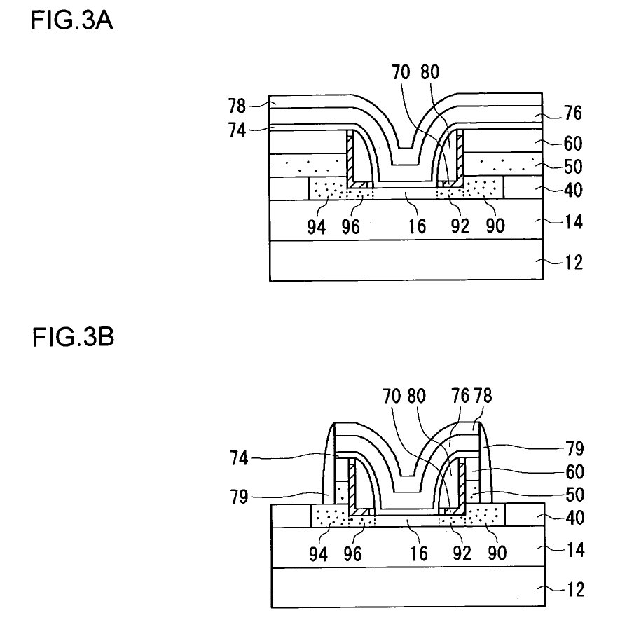

Then, as shown in FIG. 3A, by ALD (Atomic Layer Deposition) or CVD, a so-called high-k film is deposited as a gate insulating film 74, on which deposited is a gate metal layer 76. The high-k insulating film includes hafnium, zirconium, or aluminum, and more specifically, includes hafnium oxide, zirconium oxide, aluminum oxide, hafnium silicate, zirconium silicate, aluminum silicate or the like. Additionally, on the gate metal layer 76, deposited is a silicon nitride layer 78 as a hard mask. The gate metal layer 76 may also be multi-layered. For example, the gate metal layer 76 may have a first metal layer deposited on the gate insulating film 74 and a second metal layer deposited on the first metal layer, such that the first metal layer compensates the work function of the second metal layer. Although the work function is usually determined by the first metal layer, it is also possible to mix the first and second metal layers through heat treatment or the like to thereby compensate the work function.

Then, as shown in FIG. 3B, with the gate pattern masked through a lithography process, the silicon nitride layer 78 is selectively removed. Furthermore, the gate metal layer 76 underlying the silicon nitride layer 78 that has been selectively removed, the gate insulating film 74, the silicon oxide film 60, and the poly-crystal silicon layer 50 are etched away. The end point of the etching is determined based on a change in emission intensity caused as the element isolation regions 40 starts being exposed. The sidewall portion resulting from the removal by the etching may be provided, as required, with sidewalls 79 using silicon nitride. To use the silicon nitride as a stopper film during contact etching, a silicon nitride film is formed as thin as about 20 nm, on which formed is a gate insulating film such as a silicon oxide film formed at a low temperature. In the subsequent steps, contact etching, deposition of conductor materials, and formation of the conductors may be performed, thereby forming the upper structure.

FIG. 3B shows a cross-sectional structure in a source-drain direction of a semiconductor device fabricated by the semiconductor fabrication method according to the first embodiment. The semiconductor device according to this embodiment has the source region 90 and the drain region 94 formed in an elevated structure with perpendicular sidewalls. In the device, the source region 90 and the drain region 94 are in contact with the source extension region 92 and the drain extension region 96, which are provided on both sides of the SOI layer 16 in the channel region immediately under the gate. The gate electrode is made up of the gate insulating film 74 and the gate metal layer 76 and is buried in a recessed portion, formed between the source region 90 and the drain region 94, with the SOI layer 16 of the channel region disposed at the bottom thereof.

[Second Embodiment]

A method for fabricating a semiconductor device according to this embodiment commonly follows up to the step of implanting a dopant into the poly-crystal silicon layer 50 as shown in FIGS. 1A to 1D of the first embodiment. Thus, no descriptions will be given to the same steps as those of the first embodiment.

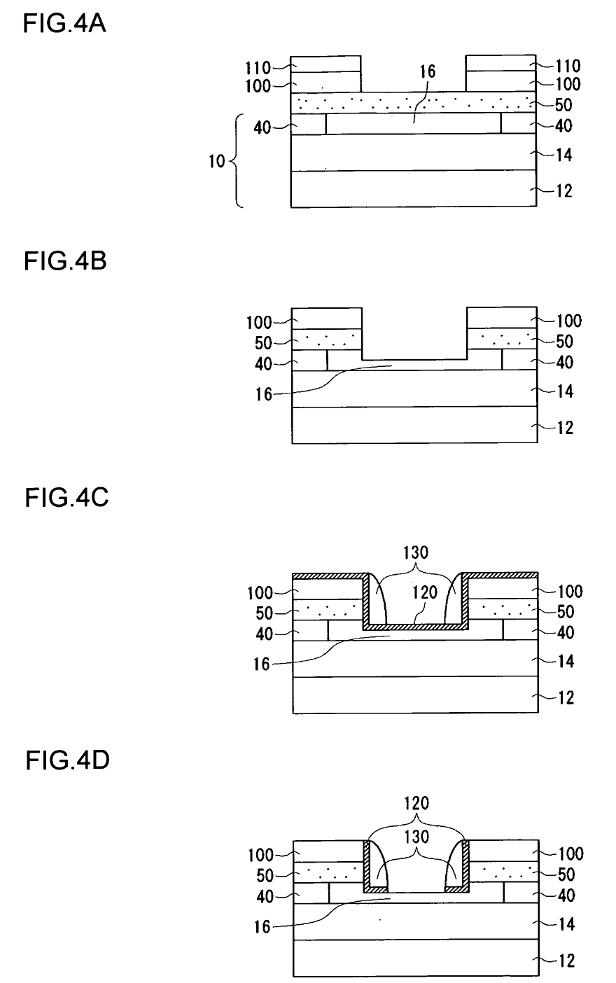

Subsequently to the steps commonly followed by the first embodiment, as shown in FIG. 4A, a silicon nitride layer 100 and a poly-crystal silicon layer 110 are deposited by CVD on the poly-crystal silicon layer 50. Thereafter, by employing as an opening of a mask a gate pattern provided through a lithography process, the silicon nitride layer 100 and the poly-crystal silicon layer 110 are selectively removed by RIE. Through this step, there is formed a recessed portion having perpendicular sidewalls with the poly-crystal silicon layer 50 disposed at the bottom thereof.

Then, as shown in FIG. 4B, the poly-crystal silicon layer 110 and the poly-crystal silicon layer 50 at the bottom of the recessed portion are etched away. Then, after the poly-crystal silicon layer 50 at the bottom of the recessed portion has been removed, the underlying SOI layer 16 is gradually removed and then the etching is terminated when it is detected based on a change in emission intensity that the silicon nitride layer has been exposed. Through this step, the SOI layer 16 in the gate region has been removed to a certain depth, such that the SOI layer 16 in the gate region is reduced in thickness, e.g., to about 20 to 30 nm. At this point in time, there is formed in the gate region a recessed portion having perpendicular sidewalls with the SOI layer 16 at its bottom. In this step, the thickness of the SOI layer 16 in the gate region can be easily changed by controlling the end point of the etching depending on the thickness of the poly-crystal silicon layer 62.

Then, a poly-crystal silicon layer 120 having a thickness of 20 to 30 nm is deposited as shown in FIG. 4C. Thereafter, a silicon oxide film of a thickness of 100 nm is deposited, and then by anisotropic etching such as RIE, a side wall spacer 130 is formed on the sidewalls of the recessed portion in the gate region.

Then, as shown in FIG. 4D, the poly-crystal silicon layer 120 exposed by RIE is etched away by the thickness of the layer deposited in FIG. 4C.

Then, as shown in FIG. SA, the exposed surface portion is thermally oxidized from the surface to a depth of about 20 nm, and thereafter, subjected to heat treatment for 10 to 20 seconds at a temperature of 1000° C. Thereafter, using DHF or BHF, the silicon oxide film on the surface is washed away by about 20 nm. Through this step, both the exposed surfaces of the poly-crystal silicon layer 120 are changed to a silicon oxide film 122. Furthermore, the dopant diffuses from the poly-crystal silicon layer 50 into the SOI layer 16 to form the source region 90 and the drain region 94 which have a perpendicular sidewall in the SOI layer 16. On both sides of the channel region immediately underlying the gate, the source extension region 92 and the drain extension region 96 are also formed which contact with the source region 90 and the drain region 94, respectively.

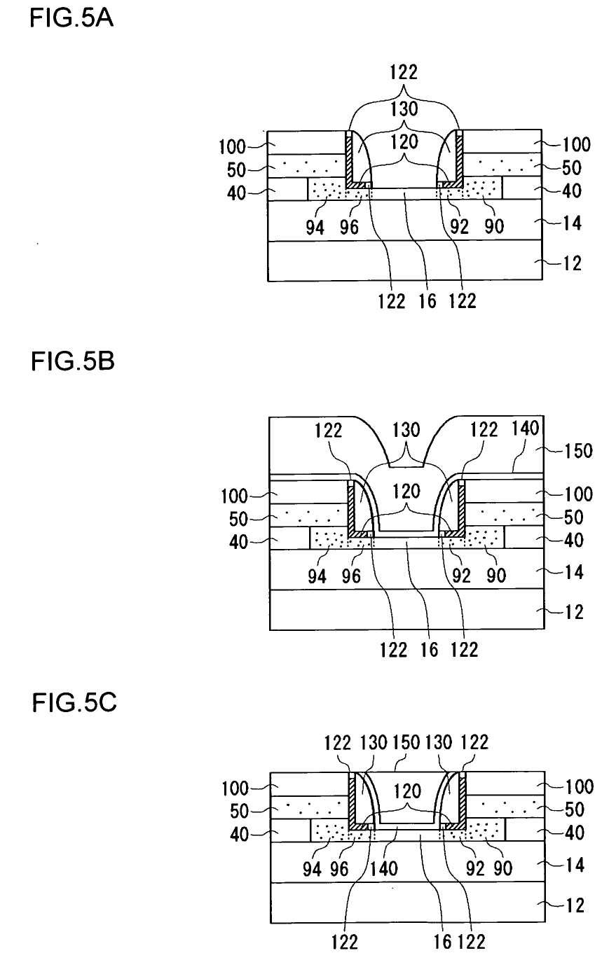

Then, as shown in FIG. 5B, by ALD or CVD, a high-k film is deposited as a gate insulating film 140, on which deposited is a gate metal layer 150. The gate metal layer 150 may also be multi-layered. For example, the gate metal layer 150 may have a first metal layer deposited on the gate insulating film 140 and a second metal layer deposited on the first metal layer, such that the first metal layer compensates the work function of the second metal layer.

Then, as shown in FIG. 5C, with the silicon nitride layer 100 employed as a stopper, the gate metal layer 150 is removed by CMP (Chemical mechanical Polishing) to flatten the surface, allowing the gate metal layer 150 to remain only in the gate region. As can be seen clearly from FIG. 5C, the gate metal layer 150 is higher than the element isolation region 40. Accordingly, without the first conductor layer immediately above the transistor layer, the gate electrode can be buried in the silicon nitride layer 100 above the element isolation regions 40 and extended to electrically connect to the gate in another active region.

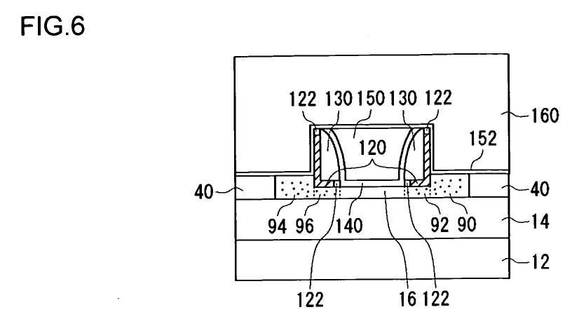

Then, as shown in FIG. 6, the silicon nitride layer 100 and the poly-crystal silicon layer 50 are etched away. The sidewall portion resulting from the removal by the etching may be provided, as required, with a sidewall using silicon nitride. In this embodiment, the silicon nitride is used as a stopper film during contact etching. In this case, a silicon nitride film 152 is formed as thin as about 20 nm, on which formed is a gate insulating film 160 such as a silicon oxide film formed at a low temperature. In the subsequent steps, contact etching, deposition of conductor materials, and formation of the conductors may be performed, thereby forming the upper structure.

FIG. 6 shows a cross-sectional structure in a source-drain direction of a semiconductor device fabricated by the semiconductor fabrication method according to the second embodiment. The semiconductor device according to this embodiment has the source region 90 and the drain region 94 formed in an elevated structure with perpendicular sidewalls. In the device, the source region 90 and the drain region 94 are in contact with the source extension region 92 and the drain extension region 96, respectively, which are provided on both sides of the SOI layer 16 in the channel region immediately under the gate. The gate electrode is made up of the gate insulating film 140 and the gate metal layer 150 and is buried in a recessed portion formed between the source region 90 and the drain region 94 with the SOI layer 16 in the channel region disposed at the bottom thereof.

[Third Embodiment]

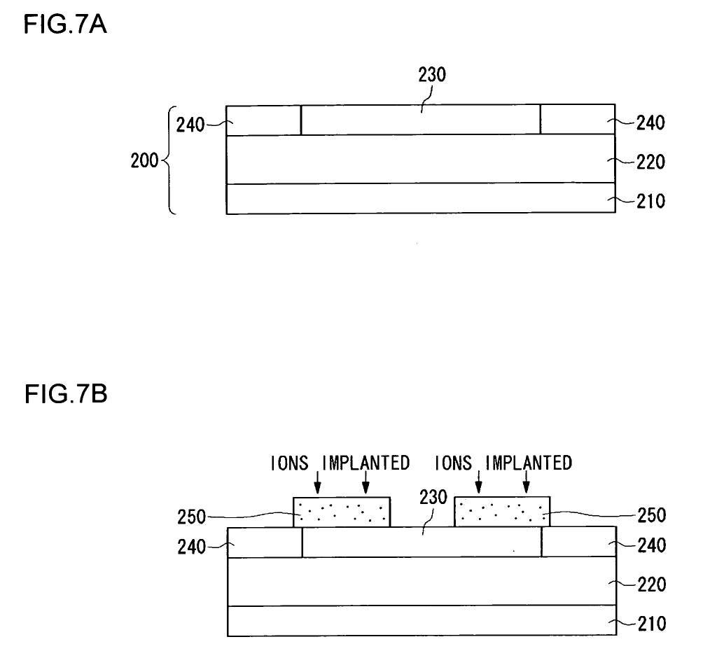

This embodiment employs, as a semiconductor substrate 200, a SOI substrate which has a SOI layer 230 separated from a Si layer 210 by a buried oxide film 220. The SOI layer 230 is reduced in advance to a thickness of about 100 nm, e.g., by oxidizing the surface and then removing the resulting oxide film. First, as shown in FIG. 7A, there are formed element isolation regions 240 on both end portions of the SOI layer 230, thereby isolating the SOI layer. The element isolation regions 240 are formed in the same steps up to the step of removing the silicon nitride layer using hot phosphoric acid in FIGS. 1A to 1D of the first embodiment.

Then, as shown in FIG. 7B, by CVD, a mixed-crystal semiconductor layer 250 of SiGe or the like is formed in a thickness of 100 nm to 150 nm on the SOI layer 230. An ionic dopant such as arsenic ions is implanted into the mixed-crystal semiconductor layer 250 at a dose of about 3E15 cm⁻². Upon forming the mixed-crystal semiconductor layer 250, ionic dopants can also be contained therein in advance, in the case of which the step of implanting the ions into the mixed-crystal semiconductor layer 250 is eliminated. Furthermore, a gate pattern for forming a gate is formed by lithography on the mixed-crystal semiconductor layer 250, and with the gate pattern employed as a mask, the mixed-crystal semiconductor layer 250 is etched by the reactive ion etching (RIE) to expose the SOI layer 230 in the gate region. Since the etch rate of SiGe is far greater than that of Si, the etching can be easily stopped at the surface of the SOI layer 230.

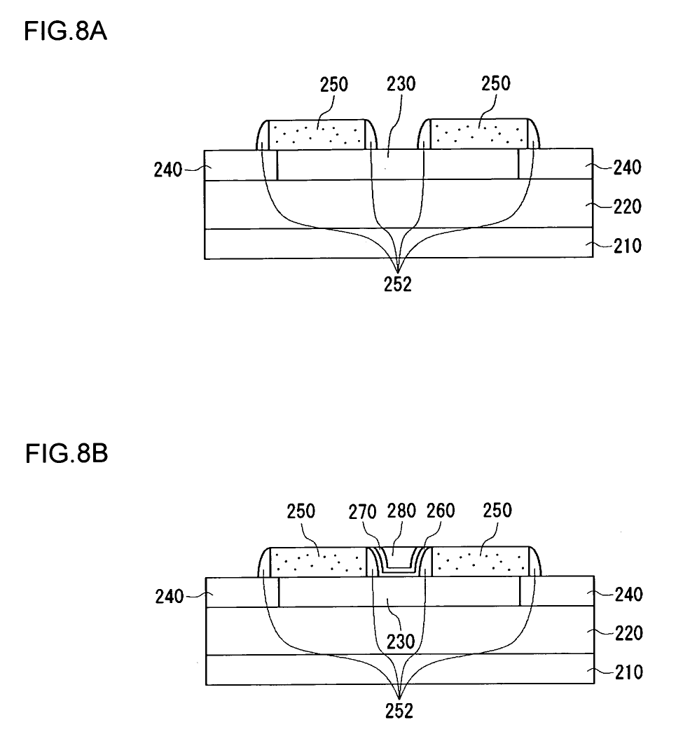

Then, as shown in FIG. 8A, an insulating material such as silicon oxide or silicon nitride is deposited on the surface and thereafter etched back by anisotropic etching, thereby forming a sidewall spacer 252 on the sidewall of each mixed-crystal semiconductor layer 250.

Then, as shown in FIG. 8B, activation annealing is done at a temperature of 1000° C. for 10 to 20 seconds, and thereafter, a sacrificial oxide film (not shown) is formed on the surface. In this step, the dopant diffuses from the mixed-crystal semiconductor layer 250 into the SOI layer 230, thereby forming a source extension region 246 and a drain extension region 248 on both sides of the SOI layer 230 in the channel region immediately under the gate. Subsequently, after the sacrificial oxide film is removed, a high-k film is deposited by ALD, CVD or the like as a gate insulating film 260, on which deposited are a first gate metal layer 270 and a second gate metal layer 280. The first gate metal layer 270 is used to compensate the work function of the second gate metal layer 280. Instead of the first gate metal layer 270, silicide may also be employed. Subsequently, by CMP and etch back, the gate insulating film 260, the first gate metal layer 270, and the second gate metal layer 280 that are present in other than the gate region are removed to bury a metal gate electrode in a recessed portion of the gate region. When an electrode material residue in-the element isolation regions 240 creates the risk of a short circuit, a resist mask with an opening on top of the element isolation regions 240 is desirably formed and then etched, thereby removing the residue.

FIGS. 8A and 8B show a cross-sectional structure in a source-drain direction of a semiconductor device fabricated by the semiconductor fabrication method according to the third embodiment. The semiconductor device according to this embodiment has the source region 90 and the drain region 94 formed in an elevated structure with perpendicular sidewalls. In the device, the source region 90 and the drain region 94 are in contact with the source extension region and the drain extension region 96, which are provided on both sides of the SOI layer 230 in the channel region immediately under the gate. The gate electrode is made up of the gate insulating film 260, the first gate metal layer 270, and the second gate metal layer 280, with the SOI layer 230 in the channel region disposed at the bottom thereof, and is buried in the recessed portion formed between the source region 90 and the drain region 94.

[Fourth Embodiment]

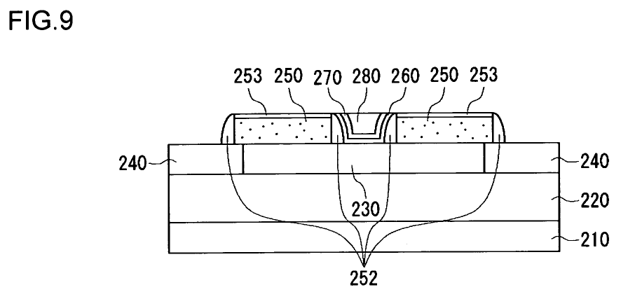

A method of fabricating a semiconductor device according to this embodiment is basically the same as that of the third embodiment except that in FIG. 7B, after the mixed-crystal semiconductor layer 250 is formed, a poly-crystal silicon layer 253 is further formed on the mixed-crystal semiconductor layer 250. An ionic dopant such as arsenic ions is implanted into the poly-crystal silicon layer 253 at a dose of about 3E15 cm⁻². Like the third embodiment, upon forming the mixed-crystal semiconductor layer 250, the ionic dopants can also be contained therein in advance, in the case of which the step of implanting the ions into the poly-crystal silicon layer 253 is eliminated. FIG. 9 is a schematic cross-sectional view showing a semiconductor device fabricated by the fabrication method according to this embodiment. The semiconductor device according to this embodiment has the poly-crystal silicon layer 253 provided on the mixed-crystal semiconductor layer 250. This configuration makes it possible to prevent the mixed-crystal semiconductor layer 250 from being etched away during etching such as in the step of forming a sidewall.

[Fifth Embodiment]

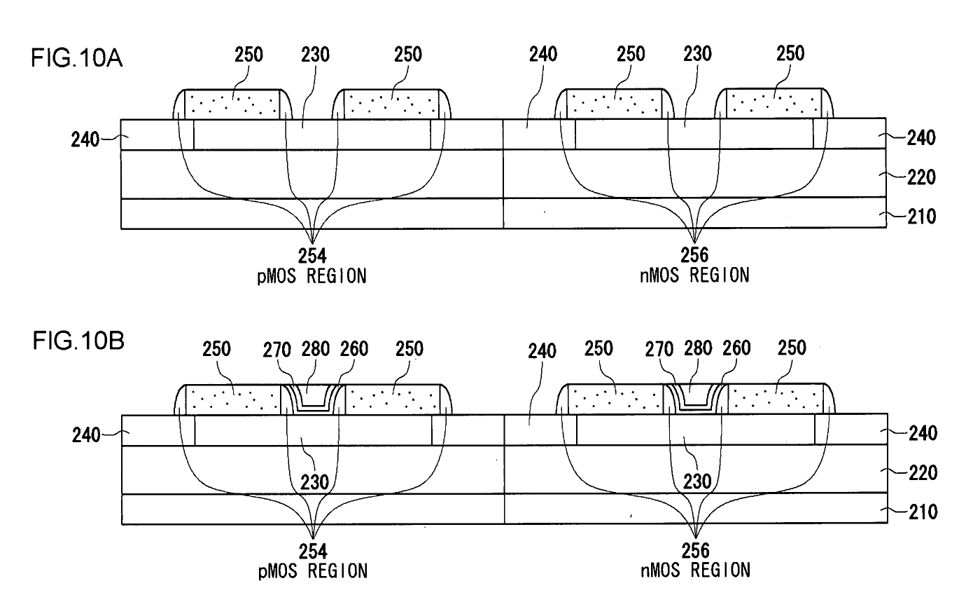

A method of fabricating a semiconductor device according to this embodiment corresponds to a modified example of fabricating a CMOS according to the third embodiment. In this embodiment, the steps shown in FIGS. 7A and 7B are performed on each of a pMOS region and an nMOS region. However, for example, an accepter such as boron is implanted as a dopant into the mixed-crystal semiconductor layer 250 formed in the pMOS region, whereas a donor such as arsenic is implanted as a dopant into the mixed-crystal semiconductor layer 250 formed in the nMOS region. Thereafter, a PSG (Phospho-silicate Glass) layer is deposited entirely on the surface and the PSG in the pMOS region is then isotropically etched away. A BSG (Boron Silicate Glass) layer is newly deposited on the entire surface and the BSG in the nMOS region is then isotropically etched away. Furthermore, the BSG in the pMOS region and the PSG in the nMOS region are anisotropically etched, thereby forming a sidewall spacer 254 of BSG on the side walls of the mixed-crystal semiconductor layer 250 in the pMOS region as shown in FIG. 10A as well as a sidewall spacer 256 of PSG on the sidewalls of the mixed-crystal semiconductor layer 250 in the nMOS region. Then, activation annealing is done. This allows a dopant of the same conductivity type as that of the dopant having diffused into the mixed-crystal semiconductor layer 250 in the pMOS region to diffuse from the sidewall spacers 254 into the SOI layer 230 in the pMOS region. At the same time, this also allows a dopant of the same conductivity type as that of the dopant having diffused into the mixed-crystal semiconductor layer 250 in the nMOS region to diffuse from the sidewall spacers 256 into the SOI layer 230 in the nMOS region. Accordingly, a source extension region and a drain extension region, which have a high dopant concentration, are formed in the pMOS region and the nMOS region, respectively.

Then, as shown in FIG. 10B, the same step as that of FIG. 8B is performed to bury a metal gate electrode in the recessed portion of the gate region in each of the pMOS region and the nMOS region. Since the source extension region and the drain extension region are formed in the pMOS region and the nMOS region, respectively, it is ensured that the source and drain regions and the channel inversion layer formed immediately under the gate are electrically connected to each other.

In FIG. 10A, after the sidewall spacers 254 and the sidewall spacers 256 are formed, a dopant of the conductivity type opposite to that of the dopant implanted into the mixed-crystal semiconductor layer 250 in the pMOS region may be implanted into the SOI layer 230 in the pMOS region. At the same time, a dopant of the conductivity type opposite to that of the dopant implanted into the mixed-crystal semiconductor layer 250 in the nMOS region may be implanted into the SOI layer 230 in the nMOS region. This allows the source extension region and the drain extension region to diffuse into the channel region, thereby preventing the channel length from becoming too short.

[Sixth Embodiment]

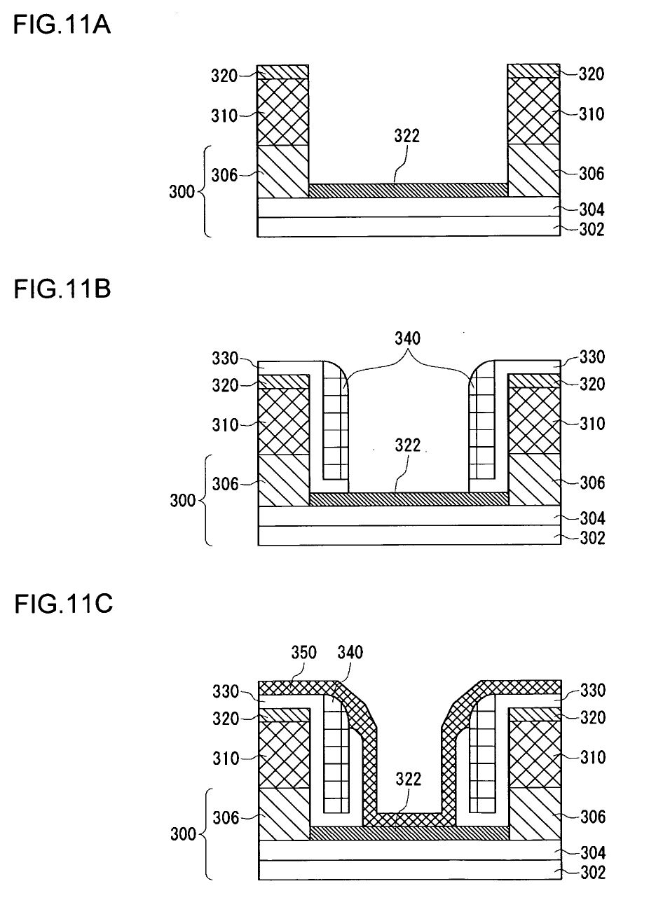

In this embodiment, first, a silicon nitride layer 310 is deposited on a semiconductor substrate 300, i.e., a SOI substrate which is made up of a Si layer 302, a SOI layer 306, and a buried oxide film 304 formed between the Si layer 302 and the SOI layer 306. Thereafter, a resist which has an opening at the center is formed by lithography, and then the silicon nitride layer 310 and the SOI layer 306 are selectively removed, thus forming a recessed portion having perpendicular sidewalls. Then, after the resist has been removed, a poly-crystal silicon layer 320 is anisotropically deposited on the semiconductor substrate 300 by sputtering or the like. Then, as shown in FIG. 11A, the poly-crystal silicon layer deposited on the side of the silicon nitride layer 310 and the SOI layer 306 is isotropically etched away. Subsequently, the poly-crystal silicon layer 320 deposited on the buried oxide film 304 is heated by being radiated with electron beams or the like, thereby allowing solid-phase epitaxial growth to occur for sequential crystal growth from the SOI layer 306 on both sides toward the center portion, thus forming a single-crystal silicon film 322.

Then, by CVD, a silicon oxide film 330 is deposited along the recessed portion. Subsequently, as shown in FIG. 11B, after poly-crystal silicon is deposited, a pair of spacers 340 are formed on both sidewalls of the recessed portion by etch back such as dry etching.

Then, on the recessed portion that is made up of the perpendicular sidewalls of the pair of spacers 340 and the single-crystal silicon film 322, a silicon oxide film is deposited and then etched back, e.g., by dry etching. Thus, the end portion of each silicon oxide film 330 on the bottom side of the recessed portion is allowed to extend upwardly along the spacers 340. Then, as shown in FIG. 11C, by CVD, a silicon nitride layer 350 is deposited on the entire surface.

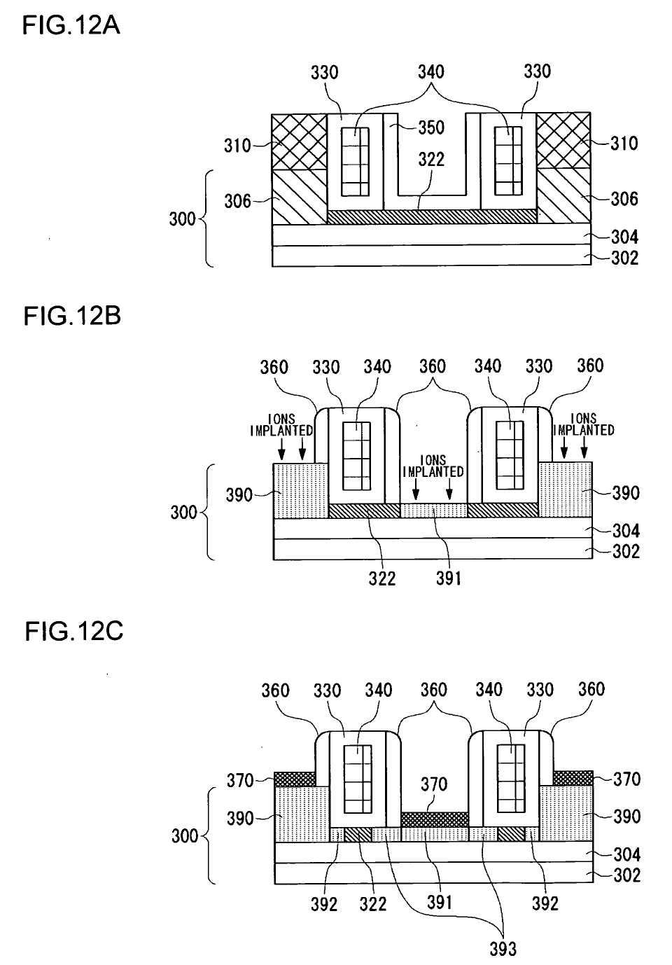

Then, the surface is smoothed by CMP to expose the silicon nitride layer 310. Furthermore, as shown in FIG. 12A, the upper portion of the spacers 340 of poly-crystal silicon is oxidized. This allows both the spacers 340 to be surrounded by the silicon oxide films 330, respectively.

Then, after the silicon nitride layer 310 is removed, spacers 360 are formed of silicon nitride or silicon oxide on both sides of both the silicon oxide films 330. Subsequently, as shown in FIG. 12B, an ionic dopant such as arsenic ions is implanted into the exposed SOI layer 306 and single-crystal silicon film 322. This allows a pair of source regions 390 to be formed on both end portions of the buried oxide film 304 and a drain region 391 to be formed on the bottom of the recessed portion.

Then, cobalt is deposited on the entire surface and then subjected to heat treatment, thereby causing a silicification reaction to occur between the cobalt and the pair of source regions 390 as well as the drain region 391. At this time, as shown in FIG. 12C, the dopant is thermally diffused from the pair of source regions 390 and the drain region 391 into the single-crystal silicon film 322. As a result, a pair of source extension regions 392 are formed which contact with the pair of source regions 390, respectively, while a pair of drain extension regions 393 are formed which contact with both ends of the drain region 391. Thereafter, as shown in FIG. 12C, non-reacted cobalt is selectively removed, thereby forming cobalt salicide 370 on the bottom of the recessed portion and both the SOI layers 306.

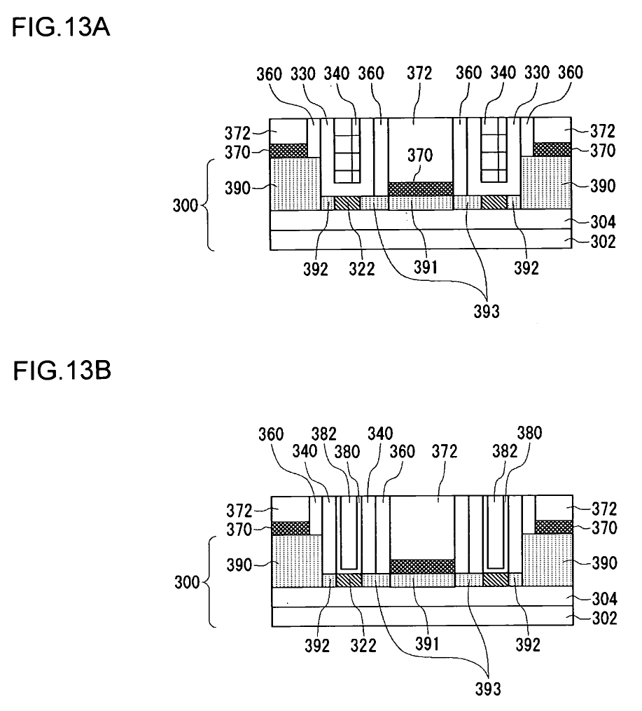

Then, a thin silicon nitride film (not shown) is deposited on the entire surface. This thin silicon nitride film is used as a stopper during contact etching. Subsequently, after a silicon oxide film 372 is deposited on the entire surface, the surface is flattened by CMP or etch back, thereby exposing the upper portion of the spacers 340 that are buried in the silicon oxide film 330, as shown in FIG. 13A.

Then, the spacers 340 buried in the silicon oxide film 330 are etched away, and then the silicon oxide film resulting from the etching on the bottom of the recessed portion is wet etched to expose the single-crystal silicon film 322. Thereafter, as shown in FIG. 13B, a high-k gate insulating film 380 is deposited on the entire surface and then a gate metal layer 382 is deposited. Then, by metal CMP or etch back, the portions of the gate insulating film 380 and the gate metal layer 382 that are not necessary for the gate are selectively removed.

FIG. 13B shows a cross-sectional structure in a source-drain direction of a semiconductor device fabricated by the semiconductor fabrication method according to the sixth embodiment. The semiconductor device according to this embodiment has a pair of the source regions 390 formed in an elevated structure with perpendicular sidewalls, and the common drain region 391. The source regions 390 are in contact with the source extension regions 392 connected to the channel region immediately under the gate, respectively. Both ends of the drain region 391 are in contact with the drain extension regions 393 connected to the channel region immediately under the gate, respectively. A pair of gate electrodes are each made up of the gate insulating film 380 and the gate metal layer 382, and are buried in a pair of respective recessed portions, which are each formed between either of the two source regions 390 and the common drain region 391, with the single-crystal silicon film 322 of the channel region disposed at the bottom thereof.

[Seventh Embodiment]

This embodiment basically follows the same procedure as that of the fabrication method of the sixth embodiment. In the descriptions that follow, explanations will not be given to the same steps as those of the sixth embodiment but only to the steps that are different from those of the sixth embodiment. This embodiment includes the same steps as those of the sixth embodiment which were described with reference to FIG. 11B. In this embodiment, a poly-crystal silicon layer is deposited on the entire surface instead of the silicon nitride layer 350. This poly-crystal silicon film is subjected to oxidation in place of the step of oxidizing the upper portion of the spacers 340 of poly-crystal silicon in FIG. 12A, thereby changing to a silicon oxide film. On the other hand, the silicon oxide film formed on the bottom of the recessed portion is selectively removed during, or before or after the step of removing the silicon nitride layer 310. Thereafter, the steps subsequent to the step of forming the spacers 360 on both sides of both the silicon oxide films 330 are performed in the same manner as in the sixth embodiment, thereby providing the same structure as that of the semiconductor device fabricated according to the sixth embodiment.

[Eighth Embodiment]

This embodiment follows the same fabrication method as that of the sixth embodiment from the step described above with reference to FIG. 11B of the sixth embodiment up to the step of depositing and then etching back, e.g., by dry etching, the silicon oxide film on the recessed portion having the spacers 340 as the sidewalls, thereby allowing the end portion of both the silicon oxide films 330 on the bottom side of the recessed portion to extend upwardly along the spacer 340 having the perpendicular sidewall.

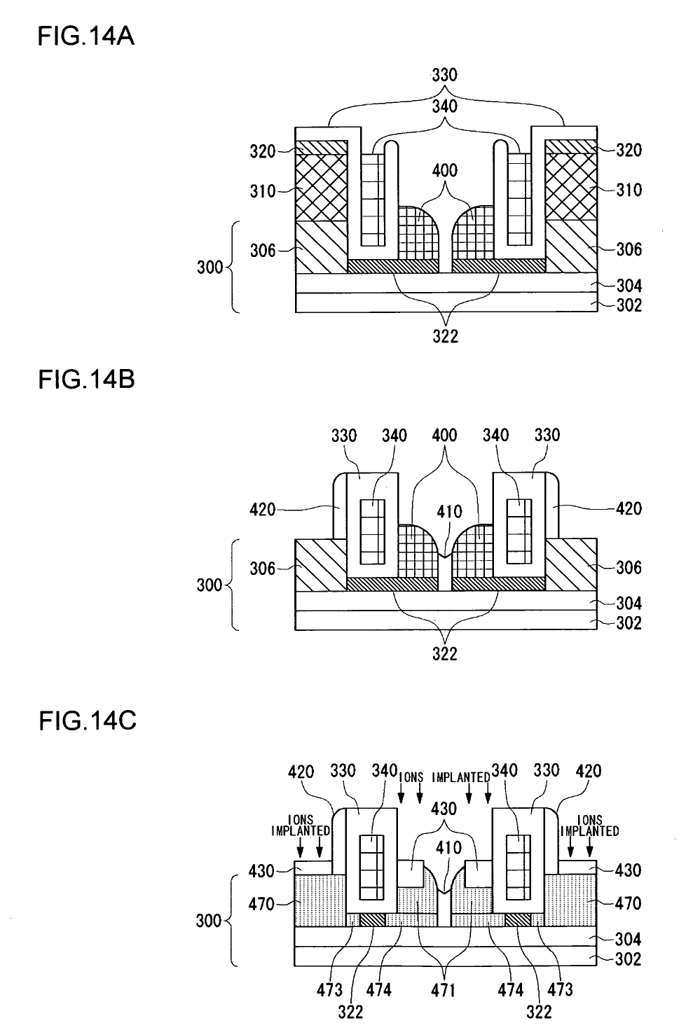

Then, in this embodiment, as shown in FIG. 14A, a poly-crystal silicon layer is deposited on the entire surface and then etched back to form a spacer 400 of poly-crystal silicon on the sidewall of both the spacers 340. At the same time, the single-crystal silicon film 322 exposed between both the spacers 400 is selectively removed to expose the buried oxide film 304. Through this step, a groove having perpendicular sidewalls is formed between both the spacers 400.

Then, as shown in FIG. 14B, the silicon oxide film 330 on both upper planar ends, the underlying poly-crystal silicon layer 320, and the silicon nitride layer 310 are etched away. Furthermore, a silicon oxide film is deposited on the entire surface and then etched back, thereby allowing a silicon oxide film 410 to be buried in the groove provided between both the spacers 400. At this time, the silicon oxide film is also buried on top of the spacers 340, allowing the buried silicon oxide film to be integrated with the silicon oxide film 330. This causes the spacer 340 to be buried in the silicon oxide film 330. Additionally, a spacer 420 of silicon oxide film is formed outside the silicon oxide film 330.

Then, an ionic dopant such as arsenic ions is implanted into the exposed SOI layers 306 and spacers 400. This allows a pair of source regions 470 to be formed on both end portions of the buried oxide films 304 and a pair of drain regions 471 to be formed being spaced apart from each other in the recessed portion. Subsequently, cobalt is deposited on the entire surface and then subjected to heat treatment, thereby causing a silicification reaction to occur between the cobalt, and the SOI layers 306 and the poly-crystal silicon of the spacers 400. At this time, as shown in FIG. 14C, the dopant is thermally diffused from the pair of source regions 470 and the pair of drain regions 471 into the respective single-crystal silicon films 322. As a result, source extension regions 473 are formed which contact with the pair of source regions 470, respectively, while drain extension regions 474 are formed which contact with the pair of the drain regions 471, respectively. Thereafter, as shown in FIG. 14C, non-reacted cobalt is selectively removed, thereby forming cobalt salicide 430.

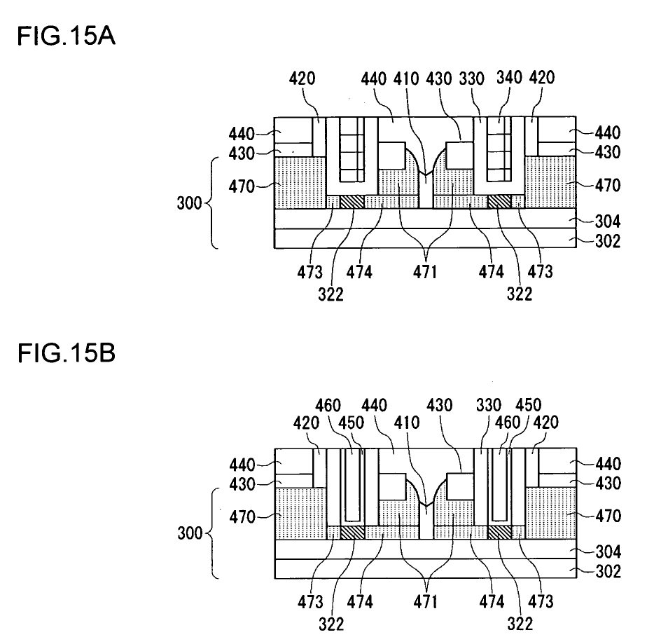

Then, a thin silicon nitride film (not shown) is deposited on the entire surface. This thin silicon nitride film can be used as a stopper during contact etching. Subsequently, after a silicon oxide film 440 is deposited on the entire surface, which is then flattened by CMP or etch back, thereby exposing the upper portion of the spacer 340 that is buried in the silicon oxide film 330, as shown in FIG. 15A.

Then, the spacer 340 buried in the silicon oxide film 330 is etched away, and then the silicon oxide film resulting from the etching on the bottom of the recessed portion is wet etched to expose the single-crystal silicon film 322. Thereafter, as shown in FIG. 15B, a high-k gate insulating film 450 is deposited on the entire surface and then a gate metal layer 460 is deposited. Then, by metal CMP or etch back, the portions of the gate insulating film 450 and the gate metal layer 460 that are not necessary for the gate are selectively removed.

FIG. 15B shows a cross-sectional structure in a source-drain direction of a semiconductor device fabricated by the semiconductor fabrication method according to the eighth embodiment. The semiconductor device according to this embodiment has a pair of the source regions 470 formed in an elevated structure with perpendicular sidewalls, and a pair of the drain regions 471 corresponding to the pair of the source regions 470. The source regions 470 are in contact with the source extension regions 473 connected to the channel region immediately under the gate, respectively. The drain regions 471 are in contact with the drain extension regions 474 connected to the channel region immediately under the gate, respectively. A pair of gate electrodes are each made up of the gate insulating film 450 and the gate metal layer 460, and are buried in a pair of respective recessed portions, which are each formed between the source region and the drain region, with the single-crystal silicon film 322 of the channel region disposed at the bottom thereof.

[Ninth Embodiment]

This embodiment follows the same fabrication method as that of the sixth embodiment from the step described above with reference to FIG. 11B of the sixth embodiment up to the step of depositing and then etching back, e.g., by dry etching, the silicon oxide film on the recessed portion having the spacers 340 as the sidewalls, thereby allowing the end portion of both the silicon oxide films 330 on the bottom side of the recessed portion to extend upwardly along the spacer 340.

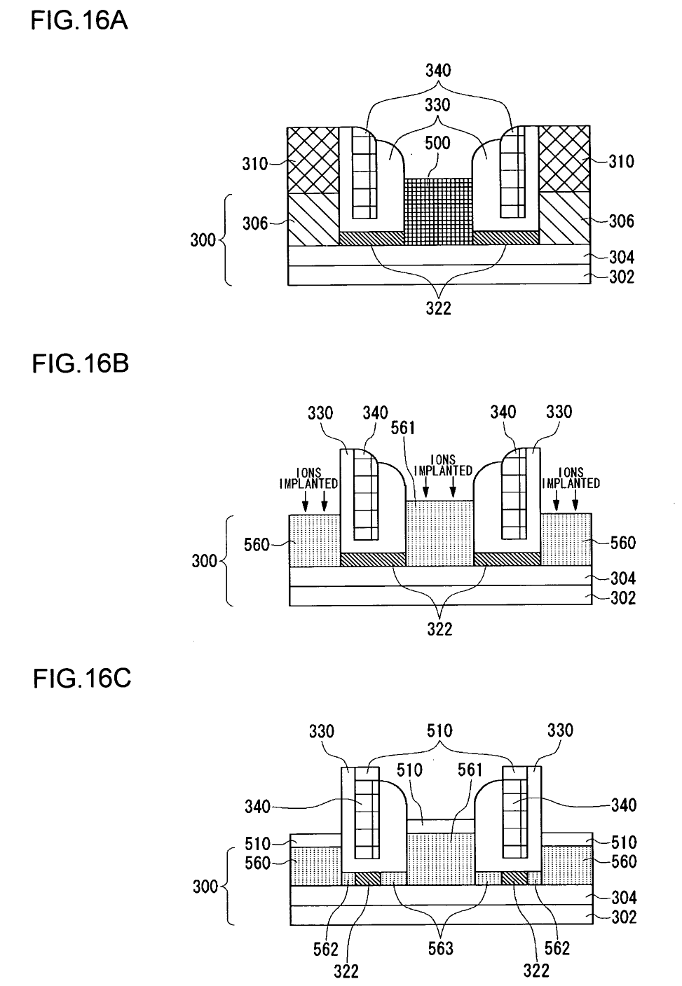

Then, in this embodiment, selectively etched away are the single-crystal silicon film 322 on the bottom of the recessed portion, the silicon oxide film 330 on both the upper planar ends, and the underlying poly-crystal silicon layer 320. Subsequently, as shown in FIG. 16A, a poly-crystal silicon layer 500 is deposited on the central recessed portion having perpendicular sidewalls and then etched back.

Then, as shown in FIG. 16B, after the silicon nitride layer 310 has been etched away, an ionic dopant such as arsenic ions is implanted into the exposed SOI layer 306 and poly-crystal silicon layer 500. This allows a pair of source regions 560 to be formed on both end portions of the buried oxide film 304 and a drain region 561 to be formed on the recessed portion. In this step, the silicon nitride layer 310 may be removed only in the device active region, thereby allowing the silicon nitride layer 310 remaining in other than the device active region to be used as a stopper in a CMP step, discussed later.

Then, cobalt is deposited on the entire surface and then subjected to heat treatment, thereby causing a silicification reaction to occur between the cobalt, and the SOI layers 306 and the poly-crystal silicon layer 500. At this time, as shown in FIG. 16C, the dopant is thermally diffused from the pair of source regions 560 and the drain region 561 into the single-crystal silicon film 322. As a result, a pair of source extension regions 562 are formed which contact with the pair of source regions 560, respectively, while a pair of drain extension regions 563 are formed which contact with both lower side portions of the drain region 561, respectively. Thereafter, as shown in FIG. 16C, non-reacted cobalt is selectively removed, thereby forming cobalt salicide 510. In this step, the cobalt salicide 510 is also formed on top of the spacers 340 but will be removed in a step discussed later.

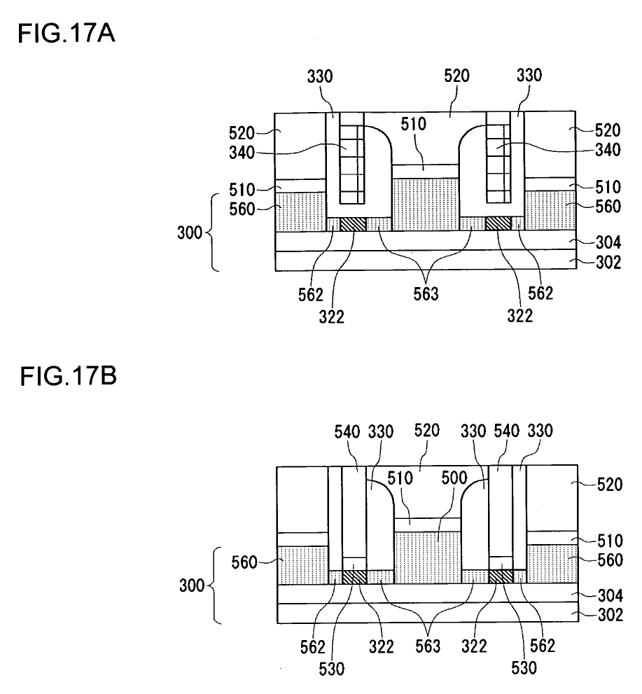

Then, a thin silicon nitride film (not shown) is deposited on the entire surface. This thin silicon nitride film is used as a stopper during contact etching. Subsequently, a silicon oxide film 520 is deposited on the entire surface, which is then flattened by CMP or etch back, thereby exposing the cobalt salicide 510 formed on the spacers 340, as shown in FIG. 17A.

Then, the cobalt salicide 510 formed on the spacers 340 and the underlying spacers 340 are etched away. Thereafter, the silicon oxide film resulting from the etching on the bottom of the recessed portion is wet etched to expose the single-crystal silicon film 322. Furthermore, as shown in FIG. 17B, a high-k gate insulating film 530 is deposited on the bottom of the recessed portion and then a gate metal layer 540 is deposited. Then, by metal CMP or etch back, the portion of the gate metal layer 540 that is not necessary for the gate is selectively removed.

FIG. 17B shows a cross-sectional structure in a source-drain direction of a semiconductor device fabricated by the semiconductor fabrication method according to the ninth embodiment. The semiconductor device according to this embodiment has a pair of the source regions 560 formed in an elevated structure with perpendicular sidewalls, and the common drain region 561. The source regions 560 are in contact with the source extension regions 562 connected to the channel region immediately under the gate, respectively. Both the lower sides of the drain region 561 are in contact with the drain extension regions 563 connected to the channel region immediately under the gate, respectively. A pair of gate electrodes are each made up of the gate insulating film 530 and the gate metal layer 540, and are buried in a pair of respective recessed portions, which are each formed between either of the source regions 560 and the drain region 561, with the single-crystal silicon film 322 of the channel region disposed at the bottom thereof.

[Tenth Embodiment]

This embodiment follows the same fabrication method as that of the sixth embodiment from the step described above with reference to FIG. 11B of the sixth embodiment up to the step of depositing and then etching back, e.g., by dry etching, the silicon oxide film on the recessed portion having the spacers 340 as the sidewalls, thereby allowing the end portion of both the silicon oxide films 330 on the bottom side of the recessed portion to extend upwardly along the spacer 340.

In the etch back such as dry etching, the silicon oxide film on the single-crystal silicon film 322 is also removed.

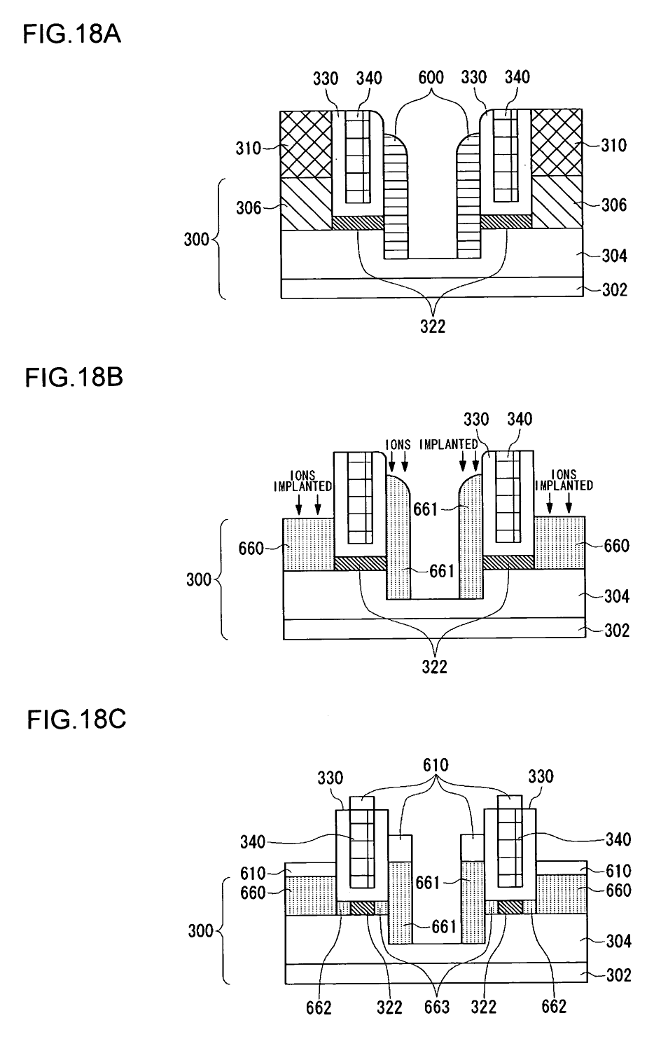

In this embodiment, the single-crystal silicon film 322 in the recessed portion is then etched away, and the buried oxide film 304 is also etched away to a predetermined depth. Thereafter, as shown in FIG. 18A, a poly-crystal silicon layer 600 is deposited and then etched back, thereby exposing the buried oxide film 304 to the bottom of the recessed portion which is formed on the poly-crystal silicon layer 600 with perpendicular sidewalls.

Then, as shown in FIG. 18B, after the silicon nitride layer 310 has been etched away, an ionic dopant such as arsenic ions is implanted into the exposed SOI layers 306 and poly-crystal silicon layer 600. This allows a pair of source regions 660 to be formed on both end portions of the buried oxide films 304 and a pair of drain regions 661 to be formed being spaced apart from each other in the recessed portion. The lower end of the drain regions 661 is lower than the upper surface of the buried oxide film 304.

The silicon nitride layer 310 is removed only in the device active region, thereby allowing the silicon nitride layer 310 remaining in other than the device active region to be used as a stopper in a CMP step, discussed later.

Then, cobalt is deposited on the entire surface and then subjected to heat treatment, thereby causing a silicification reaction to occur between the cobalt, and the SOI layers 306 and the poly-crystal silicon layer 600. At this time, as shown in FIG. 18C, the dopant is thermally diffused from the pair of source regions 660 and the pair of the drain region 661 into the corresponding single-crystal silicon film 322. As a result, source extension regions 662 are formed which contact with the pair of source regions 660, respectively, while drain extension regions 663 are formed which contact with the pair of drain regions 661, respectively. In this embodiment, since the lower end of the drain regions 661 is lower than the single-crystal silicon film 322, it can be ensured that the drain extension regions 663 and the drain regions 661 are connected to each other. Thereafter, as shown in FIG. 18C, non-reacted cobalt is selectively removed, thereby forming cobalt salicide 610. In this step, the cobalt salicide 610 is also formed on top of the spacers 340 but will be removed in a step, discussed later.

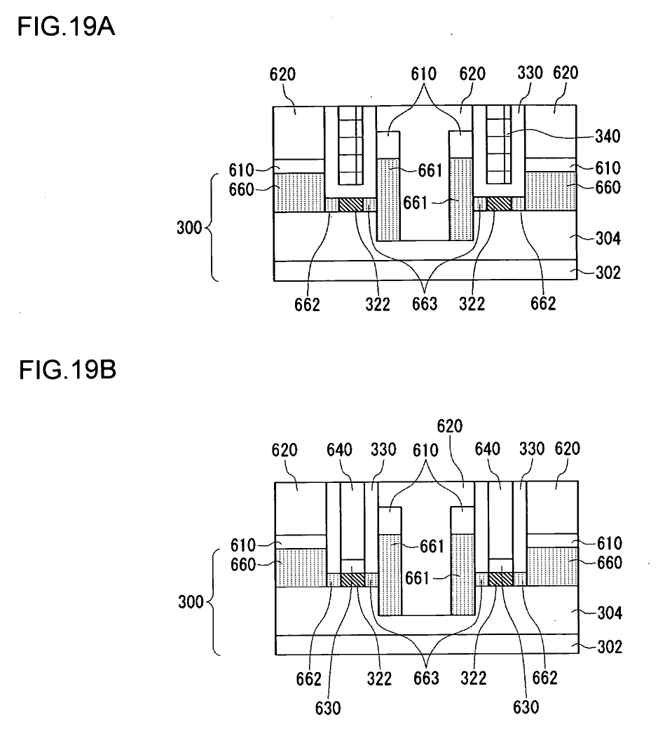

Then, a thin silicon nitride film (not shown) is deposited on the entire surface. This thin silicon nitride film is used as a stopper during contact etching. Subsequently, a silicon oxide film 620 is deposited on the entire surface, which is then flattened by CMP or etch back, thereby exposing the spacers 340 as shown in FIG. 19A.

Then, the spacers 340 are etched away. Thereafter, the silicon oxide film resulting from the etching on the bottom of the recessed portion is wet etched to expose the single-crystal silicon film 322. Furthermore, as shown in FIG. 19B, a high-k gate insulating film 630 is deposited on the bottom of the recessed portion and then a gate metal layer 640 is deposited. Then, by metal CMP or etch back, the portion of the gate insulating film 640 that is not necessary for the gate is selectively removed.

FIG. 19B shows a cross-sectional structure in a source-drain direction of a semiconductor device fabricated by the semiconductor fabrication method according to the tenth embodiment. The semiconductor device according to this embodiment has a pair of the source regions 660 formed in an elevated structure with perpendicular sidewalls, and a pair of the drain regions 661 corresponding to the pair of the source regions 660. The source regions 660 are in contact with the source extension regions 662 connected to the channel region immediately under the gate, respectively. The drain regions 661 are in contact with the drain extension regions 663 connected to the channel region immediately under the gate, respectively. A pair of gate electrodes are each made up of the gate insulating film 630 and the gate metal layer 640, and are buried in a pair of respective recessed portions, which are each formed between the source region and the drain region, with the single-crystal silicon film 322 of the channel region disposed at the bottom thereof.

The semiconductor device according to this embodiment ensures the electrical continuity between the drain region 661 and the drain extension region 663 because the drain region 661 is formed on the buried oxide film 304 that has been etched to a certain depth.

[Eleventh Embodiment]

This embodiment follows the same fabrication method as that of the sixth embodiment from the step described above with reference to FIG. 11B of the sixth embodiment up to the step of depositing and then etching back, e.g., by dry etching, the silicon oxide film on the recessed portion having the spacers 340 as the sidewalls, thereby allowing the end portion of both the silicon oxide films 330 on the bottom side of the recessed portion to extend upwardly along the spacer 340. In the etch back such as dry etching, the silicon oxide film on the single-crystal silicon film 322 is also removed.

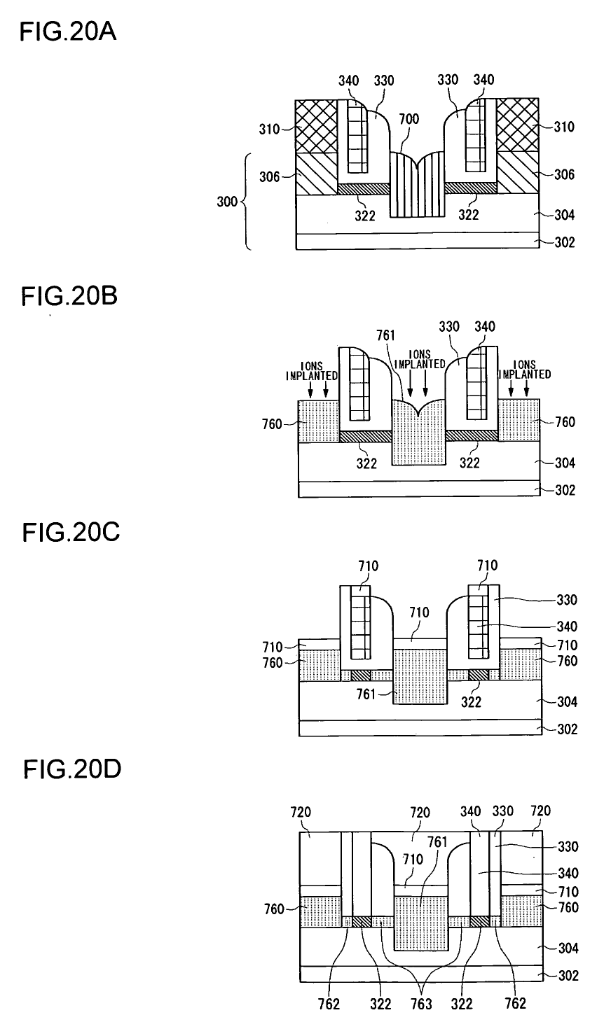

In this embodiment, the single-crystal silicon film 322 on the bottom of the recessed portion having perpendicular sidewalls and the underlying buried oxide film 304 are then etched away to a certain depth. At the same time, the silicon oxide film 330 on both the upper planar end portions and the underlying poly-crystal silicon layer 320 are also etched away. Subsequently, as shown in FIG. 20A, a poly-crystal silicon layer 700 is deposited on the central recessed portion and then etched back to bury the poly-crystal silicon layer 700 in the recessed portion.

Then, as shown in FIG. 20B, after the silicon nitride layer 310 has been etched away, an ionic dopant such as arsenic ions is implanted into the exposed SOI layer 306 and poly-crystal silicon layer 700. This allows a pair of source regions 760 to be formed on both end portions of the buried oxide films 304 and a drain region 761 to be formed in the recessed portion. The lower end of the drain region 761 is lower than the upper surface of the buried oxide film 304. The silicon nitride layer 310 is removed only in the device active region, thereby allowing the silicon nitride layer 310 remaining in other than the device active region to be used as a stopper in a CMP step, discussed later.

Then, cobalt is deposited on the entire surface and then subjected to heat treatment, thereby causing a silicification reaction to occur between the cobalt, and the SOI layers 306 and the poly-crystal silicon layer 700. At this time, as shown in FIG. 20C, the dopant is thermally diffused from the pair of source regions 760 and the drain region 761 into the corresponding single-crystal silicon film 322. As a result, a pair of source extension regions 762 are formed which contact with the pair of source regions 760, respectively, while a pair of drain extension regions 763 are formed which contact with both sides of drain region 761. Thereafter, as shown in FIG. 20C, non-reacted cobalt is selectively removed, thereby forming cobalt salicide 710. In this step, the cobalt salicide 710 is also formed on top of the spacers 340 but will be removed in a step, discussed later.

Then, a thin silicon nitride film (not shown) is deposited on the entire surface. This thin silicon nitride film is used as a stopper during contact etching. Subsequently, a silicon oxide film 720 is deposited on the entire surface, which is then flattened by CMP or etch back, thereby exposing the spacers 340 as shown in FIG. 20D.

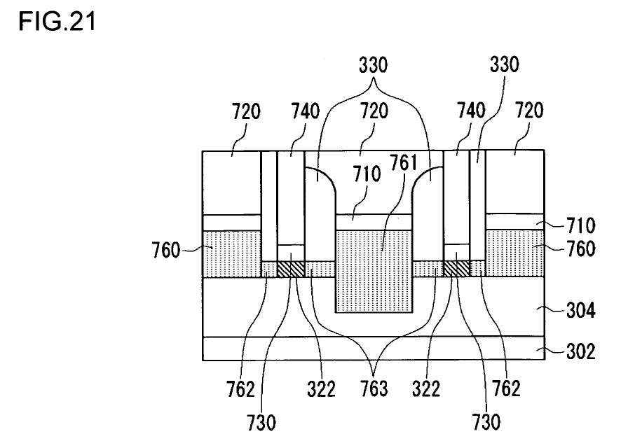

Then, the spacers 340 are etched away. Thereafter, the silicon oxide film resulting from the etching on the bottom of the recessed portion is wet etched to expose the single-crystal silicon film 322. Furthermore, as shown in FIG. 21, a high-k gate insulating film 730 is deposited on the bottom of the recessed portion and then a gate metal layer 740 is deposited. Then, by metal CMP or etch back, the portion of the gate metal layer 740 that is not necessary for the gate is selectively removed.

FIG. 21 shows a cross-sectional structure in a source-drain direction of a semiconductor device fabricated by the semiconductor fabrication method according to the eleventh embodiment. The semiconductor device according to this embodiment has a pair of the source regions 760 formed in an elevated structure with perpendicular sidewalls, and the common drain region 761. The source regions 760 are in contact with the source extension regions 762 connected to the channel region immediately under the gate, respectively. The drain region 761 is in contact at its both sides with the drain extension regions 763 connected to the channel region immediately under the gate, respectively. A pair of gate electrodes are each made up of the gate insulating film 730 and the gate metal layer 740, and are buried in the pair of respective recessed portions, which are each formed between either of the source regions and the drain region, with the single-crystal silicon film 322 of the channel region disposed at the bottom thereof.

Since the semiconductor device according to this embodiment ensures that the electrical continuity between the drain region 761 and the drain extension regions 763 because the drain region 761 is formed on the buried oxide film 304 that has been etched to a certain depth.

In each of the aforementioned embodiments, the term “perpendicular” has been used in relation to the sidewall of the source and drain. However, the sidewall of the source and drain is not necessarily orthogonal in a strict sense. The term “perpendicular” also conceptually includes “generally perpendicular” without deviating from the scope and spirit of the present invention.

As described above, the method of fabricating a semiconductor device according to the present invention makes it possible to form an elevated source drain structure having perpendicular sidewalls through a simple process without employing an epitaxial process. It is also possible to easily accomplish a higher scale of integration and a finer design rule in a semiconductor device as well as improved yields and stability during the manufacturing of the semiconductor device.

Additionally, the semiconductor device according to the present invention has a low dopant concentration in the channel region, thereby allowing for ON and OFF operations in low electric fields and thus providing reduced interface scattering and improved mobility. The semiconductor device is also provided with reduced source-drain junction capacity, thus reducing power consumption during operation. Furthermore, the semiconductor device has an elevated source drain structure using a high-k film, thereby providing reduced source-drain resistance and enhanced resistance to the short-channel effect.

These embodiments are given solely by way of illustration and the present invention is not limited thereto. It will be understood by those skilled in the art that various modifications and variations may be made based on the common knowledge in the art, and all such modifications are also intended to fall within the scope of the present invention.

1. A semiconductor device comprising:
a substrate having a semiconductor layer formed on an insulating film;
perpendicularly elevated source and drain regions at a portion sandwiched between a pair of element isolation regions formed on the substrate;
first and second insulating films formed on respective inner sidewalls of the source and drain regions; and
a gate electrode, isolated with a gate insulating film, between the first and second insulating films.

2. The semiconductor device according to claim 1, further comprising:
a source sidewall insulating film disposed between the source region and the gate electrode;
a drain sidewall insulating film disposed between the drain region and the gate electrode;
a source extension region formed under the source sidewall insulating film to connect to the source region; and
a drain extension region formed under the drain sidewall insulating film to connect to the drain region.

3. The semiconductor device according to claim 1, wherein the gate insulating film contains hafnium, zirconium, or aluminum.

4. The semiconductor device according to claim 2, wherein the gate insulating film contains hafnium, zirconium, or aluminum.

5. A method for fabricating a semiconductor device, comprising:
isolating a single-crystal silicon layer on an insulating film with a pair of element isolation regions having a perpendicular sidewall;
depositing a poly-crystal silicon layer on the isolated single-crystal silicon layer;
implanting a dopant into the poly-crystal silicon layer;
depositing an insulating film on the poly-crystal silicon layer;
forming a recessed portion by selectively removing the insulating film and the poly-crystal silicon layer in a gate bearing region and then selectively removing the single-crystal silicon layer in the gate bearing region to a predetermined depth;
forming a sidewall on the sidewall of the recessed portion;
forming source and drain regions by allowing a dopant to diffuse from the poly-crystal silicon layer to the single-crystal silicon layer; and
forming a gate electrode by depositing a conductive film after a gate insulating film is formed on a bottom of the recessed portion.

6. A method for fabricating a semiconductor device, comprising:
isolating a single-crystal silicon layer on an insulating film with a pair of element isolation regions having a perpendicular sidewall;
forming a pair of mixed-crystal semiconductors on the isolated single-crystal silicon layer;
forming a sidewall on each of sidewalls of the pair of mixed-crystal semiconductors;
implanting a dopant into the pair of mixed-crystal semiconductors; and
forming a gate insulating film and then depositing a conductive film to thereby form a gate electrode on a bottom of a gate bearing region between the pair of mixed-crystal semiconductors.

7. A method for fabricating a semiconductor device, comprising:
forming an insulating layer on a single-crystal silicon layer on an insulating film;
forming a recessed portion having a perpendicular sidewall by selectively removing the insulating layer and the single-crystal silicon layer in a gate bearing region;
forming a poly-crystal silicon film on a bottom of the recessed portion and then epitaxially growing the poly-crystal silicon film to form a single-crystal silicon film;
forming a pair of gate forming spacers on the single-crystal silicon film, the spacers having a perpendicular sidewall buried in an insulating substance;
implanting a dopant into the single-crystal silicon film between the pair of gate forming spacers and into the single-crystal silicon layer outside the pair of gate forming spacers;
forming a salicide on top of a region having the dopant implanted therein;
removing the pair of gate forming spacers and the underlying insulating substance to form a pair of recessed portions and exposing the single-crystal silicon film on the bottom of the pair of recessed portions;
forming a gate insulating film on the bottom of the pair of recessed portions; and
then depositing a conductive film to form a pair of gate electrodes via the gate insulating film.

8. A method for fabricating a semiconductor device, comprising:
forming an insulating layer on a single-crystal silicon layer on an insulating film;
forming a recessed portion having a perpendicular sidewall by selectively removing the insulating layer and the single-crystal silicon layer in a gate bearing region;
forming a poly-crystal silicon film on a bottom of the recessed portion and then epitaxially growing the poly-crystal silicon film to form a single-crystal silicon film;
forming a pair of gate forming spacers on the single-crystal silicon film, the spacers having a perpendicular sidewall buried in an insulating substance;
selectively removing the single-crystal silicon film between the pair of gate forming spacers and then selectively removing the underlying insulating film to a predetermined depth;
forming a poly-crystal silicon film on an inner sidewall of the pair of gate forming spacers;
implanting a dopant into the poly-crystal silicon film and into the single-crystal silicon layer outside the pair of gate forming spacers;
forming a salicide on top of a region having the dopant implanted therein;
removing the pair of gate forming spacers and the underlying insulating substance to form a pair of recessed portions and exposing the single-crystal silicon film on the bottom of the pair of recessed portions;
forming a gate insulating film on the bottom of the pair of recessed portions; and
then depositing a conductive film to form a pair of gate electrodes via the gate insulating film.
